(19) United States
(12) Patent Application Publication
(10) Pub. No.: US 2005/0147926 A1
(43) Pub. Date: Jul. 7, 2005

(54) Method for processing photoresist

(75) Inventors: Hsiu-Chun Lee, Taipei (TW); Tse-Yao Huang, Taipei (TW); Yi-Nan Chen, Taipei (TW); Chih-Ta Wang, Taipei (TW)

Correspondence Address: BACON & THOMAS, PLLC, 625 SLATERS LANE, FOURTH FLOOR, ALEXANDRIA, VA, 22314, US

(73) Assignee: Nanya Technology Corporation, Taoyuan (TW)

(21) Appl. No.: 10/749,590

(22) Filed: Jan. 2, 2004

(51) Int. Cl. G03F 7/00; G03F 7/36

(52) U.S. Cl. 430/322; 216/67; 430/323

(57) ABSTRACT

Disclosed is a method for processing photoresist. The method of the present invention performs Ar plasma process to the photoresist after or before the photoreisist is formed into a pattern to make the photoresist dense.

### BACKGROUND OF THE INVENTION

1. Field of the Invention

The present invention relates to a semiconductor device process, more specifically, to a method for processing photoresist in semiconductor process.

2. Description of the Prior Art

In semiconductor integrated circuit process, photoresist is widely used to define positions to be etched and the like.

For instance, there is a process to make communication between two metal layers in the production of DRAM device, as shown in FIG. 1. In this drawing, reference number 10 indicates a first metal layer, 11 indicates a dielectric layer, 12 indicates a second metal layer, and 13 indicates a via defined in the dielectric layer 11, where the via 13 is filled with metal to connect the first metal layer 10 with the second metal layer 12.

Photoresist is used to define the portions to be etched and portions to be maintained in the second metal layer 12 to form a predetermined pattern. If the photoresist layer is too thick, the resolution of the subsequent etching process will be degraded. In addition, the aspect ratio of the left photoresist will be too large, thereby causing some problems. Accordingly, in order to avoid using a thick photoresist layer, a hard mask 14 is applied, then a thin photoresist layer 15.

Due to the use of the hard mask 14, it is not necessary to form a thick photoresist layer, so that the problem of resultion degradation is avoided. However, it is difficult to remove the hark mask after the etching is completed.

Therefore, there is a need for a solution to overcome the problems stated above. The present invention satisfies such a need.

### SUMMARY OF THE INVENTION

An objective of the present invention is to provide a method for processing photoresist, which can compact photoresist, so as to reduce the thickness of a photoresist layer while maintain equivalent capability of anti-etching.

According to an aspect of the present invention, in the method for processing photoresist, the photoresist is processeded by plasma so that the photoresist is compacted after or before forming a pattern.

According to another aspect of the present invention, in the method for processing photoresist, the photoresist is processed by argon plasma.

### BRIEF DESCRIPTION OF THE DRAWINGS

The following drawings are only for illustrating the mutual relationships between the respective portions and are not drawn according to practical dimensions and ratios. In addition, the like reference numbers indicate the similar elements.

FIG. 1 shows a step in the prior art DRAM device process, in which two metal layers are communicated, and a pattern is to be formed; and

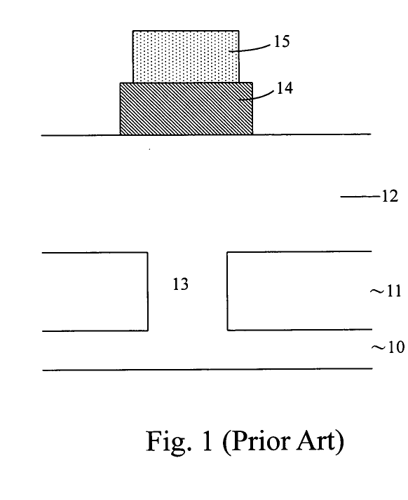

FIG. 2 shows a step in a method in accordance with the present invention, in which two metal layers are communicated, and a pattern is to be formed.

### DETIALED DESCRIPTION OF THE PREFERRED EMBODIMENT

An embodiment of the present invention will be described in detail with reference to the accompanying drawings.

The present invention proposes a method. By using this method, it is not necessary to use a hard mask when forming a pattern in a metal layer, for instance. In addition, the thickness of the photoresist can be reduced.

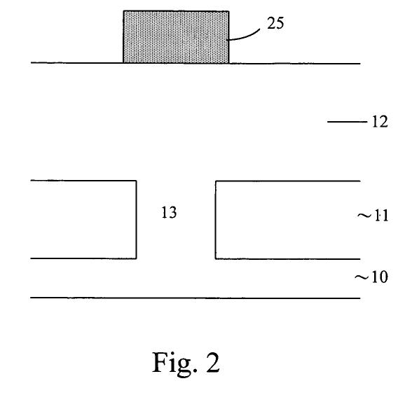

Take the process of communicating two metal layers in DRAM device as an example, with reference to FIG. 2, reference number 10 indicates a first metal layer, 11 indicates a dielectric layer, 12 indicates a second metal layer, and 13 indicates a via formed in the dielectric layer 11. The via 13 is filled with metal to connect the first metal layer 10 with the second metal layer 12.

To form a pattern in the second metal layer 12, a thick layer of photoresist is applied and is defined with a pattern using a mask. Subsequently, exposing, developing and imaging are performed, then the unnecessary portions of the photoresist are removed, and the necessary of the photoresist are maintained as a predetermined pattern. The left photoresist 25 is processed by plasma so as to compact the photoresist. In this embodiment, it is preferable to use Ar plasma. With the photoresist 25 compacted by plasma processing, the thickness of the photoresist is reduced, while the capability of anti-etching is maintained unchanged. For example, the original thickness of the photoresist is 1.4 μM. After being processed by Ar plasma, the thickness of the photoresist becomes 1.2 μM, however, the anti-etching capability of the compacted photoresist with the thickness of 1.2 μM is correspondent with that of an unprocessed photoresist layer with a thickness of 1.4 μM.

In the embodiment described above, the photoresist is processed by Ar plasma after the photoresist is formed with the pattern. However, it is also possible to perform the Ar plasma processing before the photoresist is formed with the pattern. That is, after the photoresist is applied, the photoresist is processed with Ar plasma, and the processed photoresist is then formed with a pattern.

According to the present invention, by using plasma to process the photoresist, the thickness of the photoresist is reduced, while the anti-capability thereof remains as original. Therefore, the need for using hard mask is avoided.

While the embodiment of the present invention is illustrated and described, various modifications and alterations can be made by persons skilled in this art. The embodiment of the present invention is therefore described in an illustrative but not restrictive sense. It is intended that the present invention may not be limited to the particular forms as illustrated, and that all modifications and alterations which maintain the spirit and realm of the present invention are within the scope as defined in the appended claims.

1. A method for processing photoresist, said method comprising steps of:
forming a layer of photoresist on a semiconductor structure;
defining a predetermined pattern on the photoresist;
removing unnecessary portions of the photoresist and maintaining necessary portions of the photoresist to form the predetermined pattern; and
performing compacting process to the left photoresist.

2. The method as claimed in claim 1, wherein the compacting process comprises plasma process to make the photoresist dense.

3. The method as claimed in claim 2, wherein the plasma process uses argon plasma.

4. A method for processing photoresist, said method comprising steps of:
forming a layer of photoresist on a semiconductor structure;
performing compacting process to the photoresist; and
forming the photoresist with a predetermined pattern.

5. The method as claimed in claim 4, wherein the compacting process comprises plasma process to make the photoresist dense.

6. The method as claimed in claim 5, wherein the plasma process uses argon plasma.
